(19) United States
(12) Patent Application Publication
(10) Pub. No.: US 2008/0283954 A1
(43) Pub. Date: Nov. 20, 2008

(54) Image sensor and method for manufacturing the same

(75) Inventor: Cheon Man Shim, Seoul (KR)

Correspondence Address: THE LAW OFFICES OF ANDREW D. FORTNEY, PH.D., P.C., 401 W FALLBROOK AVE STE 204, FRESNO, CA, 93711-5835, US

(73) Assignee: Dongbu HiTek Co., Ltd.

(21) Appl. No.: 12/152,384

(22) Filed: May 13, 2008

(30) Foreign Application Priority Data
May 16, 2007 (KR) 10-2007-0047588

(51) Int. Cl. H01L 31/105; H01L 31/18

(52) U.S. Cl. 257/443; 438/73; 257/E31.061

(57) ABSTRACT

Provided are an image sensor and a method for manufacturing the same. The image sensor includes a substrate, a first electrode, an intrinsic layer, a second conductive type conduction layer, and a second electrode. Circuitry including a lower interconnection is disposed on the substrate. The first electrode, the intrinsic layer, and the second conductive type conduction layer are sequentially stacked on the substrate. The second electrode is disposed on the second conductive type conduction layer and includes a non-explosive transparent electrode.

### CROSS-REFERENCE TO RELATED APPLICATIONS

The present application claims priority under 35 U.S.C. 119 and 35 U.S.C. 365 to Korean Patent Application No. 10-2007-0047588 (filed on May 10, 2007), which is hereby incorporated by reference in its entirety.

### BACKGROUND

Embodiments of the present invention relate to an image sensor and a method for manufacturing the same.

A related art complementary metal oxide silicon (CMOS) image sensor includes a photodiode region (not shown) and a transistor region. The photodiode region converts light to an electric signal. The transistor region processes the electric signal.

The CMOS image sensor includes a photodiode and a transistor which is horizontally arranged on the photodiode.

As a matter of course, although the horizontal type CMOS image sensor has merits with reference to a charge coupled device (CCD) image sensor, the horizontal type CMOS image sensor should be more improved.

That is, according to the horizontal type CMOS image sensor, the photodiode is horizontally adjacent to the transistor on the substrate. Therefore, an additional area is required for the photodiode region. As a result, a fill factor of the image sensor is reduced, and thus resolution of the horizontal type CMOS image sensor is limited.

In addition, it is difficult to optimize a process of simultaneously manufacturing the photodiode and the transistor of the CMOS image sensor. That is, a shallow junction is required in rapid transistor processes in order to reduce sheet resistance. However, the shallow junction may be inappropriate for the photodiode.

### SUMMARY

Embodiments of the invention provide an image sensor in which transistor circuitry and a photodiode are newly stacked and a method for manufacturing the image sensor.

Embodiments also provide an image sensor capable of adopting a non-explosive transparent electrode and a method for manufacturing the image sensor.

Embodiments also provide an image sensor capable of adopting a transparent electrode having a low manufacturing cost and a method for manufacturing the image sensor.

Embodiments also provide an image sensor capable of preventing cross talk between pixels and a method for manufacturing the image sensor.

Embodiments also provide an image sensor capable of improving resolution and sensitivity together and a method for manufacturing the image sensor.

Embodiments also provide an image sensor in which a vertical type photodiode is adopted to prevent defects occurring in the photodiode and a method for manufacturing the image sensor.

In one embodiment, an image sensor includes: a substrate including circuitry with a lower interconnection; first electrodes, intrinsic layers, and second conductive type conduction layers in sequence on the substrate; and second electrodes on the second conductive type conduction layers, respectively, the second electrode including a transparent electrode.

In another embodiment, a method for manufacturing an image sensor includes: forming circuitry including a lower interconnection on a substrate; sequentially forming a first electrode, an intrinsic layer, and a second conductive type conduction layer on the substrate; and forming a second electrode on the second conductive type conduction layers, the second electrode including a transparent electrode.

The details of one or more embodiments are set forth in the accompanying drawings and the description below. Other features will be apparent from the description and drawings, and from the claims.

### BRIEF DESCRIPTION OF THE DRAWINGS

FIG. 1 is a cross-sectional view of an image sensor according to a first embodiment.

FIG. 2 is a cross-sectional view of an image sensor according to a second embodiment.

### DETAILED DESCRIPTION OF THE EMBODIMENTS

Hereinafter, an image sensor and a method for manufacturing the same will be described in detail with reference to the accompanying drawings.

In the following description, it will be understood that when a layer (or film) is referred to as being ‘on’ another layer or substrate, it can be directly on the other layer or substrate, or intervening layers may also be present. Further, it will be understood that when a layer is referred to as being ‘under’ another layer, it can be directly under the other layer, and one or more intervening layers may also be present. In addition, it will also be understood that when a layer is referred to as being ‘between’ two layers, it can be the only layer between the two layers, or one or more intervening layers may also be present.

### First Embodiment

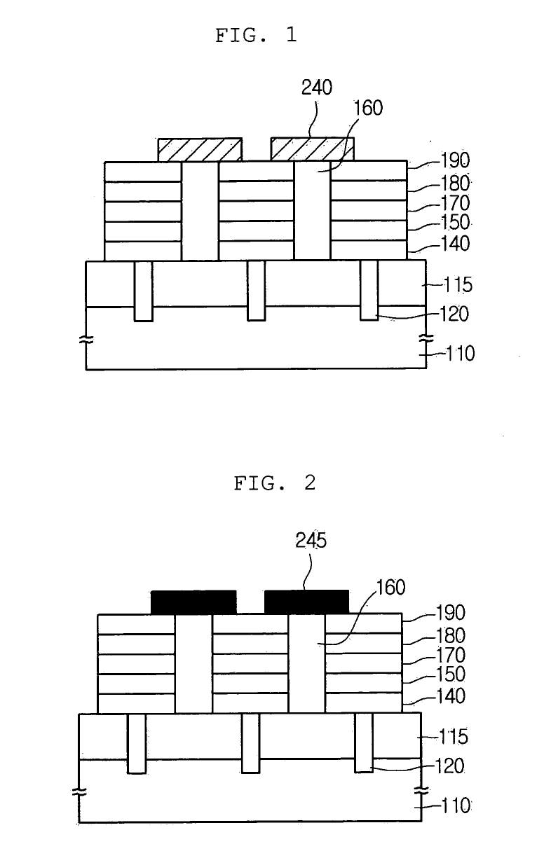

FIG. 1 a cross-sectional view of an image sensor according to a first embodiment of the invention.

Although first electrodes 140, intrinsic layers 170, second conductive type conduction layers 180, and second electrodes 190 are exemplarily illustrated in FIG. 1, the present disclosure is not limited thereto. Here, the first electrodes 140 are isolated from each other, and the intrinsic layers 170 are isolated from each other. Also, the second conductive type conduction layers 180 are isolated from each other, and the second electrodes 190 are isolated from each other.

An image sensor according to a first embodiment includes a substrate 110, the first electrodes 140, the intrinsic layers 170, the second conductive type conduction layers 180, and second electrodes 190. CMOS circuitry including a lower interconnection 120 is disposed on the substrate 110. The first electrode 140, the intrinsic layer 170, and the second conductive type conduction layer 180 are sequentially stacked on the substrate 110. The second electrode 190 includes a non-explosive transparent electrode and is disposed on the second conductive type conduction layer 180.

The first electrodes 140 may be isolated from each other, and the intrinsic layers 170 may be isolated from each other. Also, the second conductive type conduction layers 180 may be isolated from each other, and the second electrodes 190 may be isolated from each other. A dielectric 160 may be further disposed between the first electrodes 140, between the intrinsic layers 170, between the second conductive type conduction layers 180, and between the second electrodes 190.

The second electrode 190 includes the non-explosive transparent electrode. For example, the second electrode 190 may comprise, without limitation, Al-doped ZnO, Ga-doped zinc oxide, and Al and Ga-doped ZnO.

A first conductive type conduction layer 150 may be between the first electrode 140 and the intrinsic layer 170.

In the image sensor according to the first embodiment, transistor circuitry and a photodiode are vertically stacked.

According to the first embodiment, the transparent electrode using Al-doped ZnO or Ga-doped zinc oxide is adopted to provide the image sensor including the non-explosive transparent electrode. The first embodiment can provide an image sensor in which a transparent electrode using Al-doped ZnO or Ga-doped zinc oxide is adopted to reduce a manufacturing cost and a method for manufacturing the same.

Hereinafter, a method for manufacturing an image sensor according to the first embodiment will be described with reference to FIG. 1.

CMOS circuitry including a lower interconnection 120 is formed on a substrate 110. The CMOS circuitry generally includes transistors for a unit pixel (e.g., a transfer transistor in direct communication with the photodiode; a select transistor and a drive transistor in electrical communication with the transfer transistor, the drive transistor providing an output of the unit pixel; an optional reset transistor for resetting a charge stored on the photodiode or on a node in the unit pixel to a predetermined value; etc.) and optional local interconnects between two or more terminals of such transistors. A lower interlayer dielectric 115 is formed on the substrate 110, and a lower trench is formed in the lower interlayer dielectric 115 and the substrate 110 (generally by photolithographic masking and etching). The lower interconnection 120 (which may comprise a metal such as tungsten, aluminum, copper, titanium, tantalum, etc.; a [semi]conductor such as [doped] polysilicon; a conductive metal compound such as a metal silicide or a metal nitride; or a combination thereof) is then formed in the lower trench.

A first electrode 140, an optional first conductive type conduction layer 150, an intrinsic layer 170, a second conductive type conduction layer 180, and a second electrode 190 are sequentially stacked on the substrate 110.

A barrier metal layer and/or adhesive metal layer (not shown) may be further formed on the substrate 110 as a lowermost part of the first electrode 140. For example, the adhesive metal layer may comprise aluminum, titanium or tantalum, and the barrier metal layer may comprise one or more of tungsten, titanium, tantalum, and nitrides thereof.

The first electrode 140 is formed on the barrier metal layer. The first electrode 140 may comprise various conductive materials including a metal, an alloy, or a silicide. For example, the first electrode 140 may comprise one or more of aluminum, copper, and cobalt.

A first conductive type conduction layer 150 is formed on the first electrode 140. Alternatively, the first conductive type conduction layer 150 is not formed, and the following process may be performed. The first conductive type conduction layer 150 may serve as an N-layer of a PIN diode according to the embodiment. That is, the first conductive type conduction layer 150 may be, but is not limited to, an N-type conductive type conduction layer. The first conductive type conduction layer 150 may include, but is not limited to, an n-doped amorphous or polycrystalline silicon. That is, the first conductive type conduction layer 150 may comprise one or more of a-Si:H, a-SiGe:H, a-SiC, a-SiN:H, and a-SiO:H in which the amorphous silicon (“a-Si” in the preceding list of materials) is doped with Ge, C, N, or O. Alternatively, the first conductive type conduction layer 150 may comprise polysilicon doped with phosphorous (P), arsenic (As) or antimony (Sb).

The first conductive type conduction layer 150 may be formed using a chemical vapor deposition (CVD) method such as a plasma enhanced chemical vapor deposition (PECVD) method. For example, the first conductive type conduction layer 150 may comprise amorphous silicon, formed from silane (SiH₄) gas mixed with PH₃ or P₂H₅ by the PECVD method.

The intrinsic layer 170 is formed on the first conductive type conduction layer 150. The intrinsic layer 170 may serve as an I-layer of the PIN diode according to the embodiment.

The intrinsic layer 170 may include an n-doped or undoped amorphous silicon. The intrinsic layer 170 may be formed using the CVD method such as the PECVD method. For example, the intrinsic layer 170 may comprise amorphous silicon which is formed using silane (SiH₄) gas by the PECVD method. In one embodiment, the silane gas used to form the intrinsic layer 170 does not contain a dopant or dopant source;

The second conductive type conduction layer 180 is formed on the intrinsic layer 170. The second conductive type conduction layer 180 and the intrinsic layer 170 may be formed in a continuous process. The second conductive type conduction layer 180 may serve as a P-layer of the PIN diode according to the embodiment. That is, the second conductive type conduction layer 180 may be, but is not limited to, a P-type conduction layer. The second conductive type conduction layer 180 may thus include, but is not limited to, a p-doped amorphous or polycrystalline silicon.

The second conductive type conduction layer 180 may be formed using the CVD method such as the PECVD method. For example, the second conductive type conduction layer 180 may comprise amorphous silicon formed from silane (SiH₄) gas mixed with a boron source. (e.g., BF₃, diborane [B₂H₆] or a higher-order borane having 4 or more boron atoms, etc.) by the PECVD method.

The second electrode 190 is formed on the second conductive type conduction layer 180. The second electrode 190 may include a transparent electrode having high light transmittance and high conductivity as well as a non-explosive material.

For example, the second electrode 190 may comprise, but is not limited to, one of Al-doped ZnO, Ga-doped zinc oxide, and Al- and Ga-doped ZnO (e.g., zinc oxide doped with both and Ga). For example, when the second electrode 190 comprises Al-doped ZnO (ZnO:Al₂O₃), the second electrode 190 may include ZnO in which Al is present in an amount of from about 2.0 to about 10.0 atomic percent relative to Zn atoms, or alternatively, Zn and O atoms. When the second electrode 190 comprises Ga-doped ZnO (ZnO:Ga₂O₃), the second electrode 190 may include ZnO in which Ga is present in an amount of from about 0.5 to about 5.0 atomic percent relative to Zn atoms, or alternatively, Zn and O atoms. When the second electrode 190 comprises Al and Ga-doped ZnO, the second electrode 190 may include ZnO in which Ga is present in an amount of from about 0.5 to about 5.0 atomic percent relative to Zn atoms, or alternatively, Zn, Al and O atoms, and Al is present in an amount of from about 2.0 to about 10.0 atomic percent relative to Zn atoms, or alternatively, Zn, Ga and O atoms.

A glass substrate may be used as the substrate 110. The glass substrate can be rotated while argon (Ar) gas flows into a plasma chamber containing the substrate to perform a sputtering process. The second electrode 190 can be formed using at least one of a sputtering system (e.g., the sputtering system described supra in this paragraph), an e-beam evaporation system, a molecular beam epitaxy (MBE) system and a laser system. The second electrode 190 is formed at a temperature ranging from about room temperature to about 400° C. to secure thermal stability of the interconnection layer 120 and the dielectric 115. For example, room temperature may be a temperature ranging from about 10° C. to about 25° C., 15° C. to about 30° C., or other temperature within one of these ranges.

The first electrode 140, the intrinsic layer 170, the second conductive type conduction layer 180, and the second electrode 190 are selectively etched to form a trench or a plurality of trenches (not shown). A dielectric 160 is then formed in the trench(es) to electrically isolate the first electrode 140, the intrinsic layer 170, the second conductive type conduction layer 180, and the second electrode 190 from each other. Each unit pixel is thereby completely isolated from adjacent pixels by the dielectric 160. For example, the dielectric 160 may comprise one or more oxide (e.g., silicon dioxide or a thermal oxide), nitride (e.g., silicon nitride or silicon oxynitride), and low-k dielectric (e.g., hafnium dioxide) layers. After deposition into the trench(es), a planarization process and a cleaning process are performed on the dielectric 160.

There may be further formed an upper interconnection 240 electrically connecting the second electrode 190 to an adjacent second electrode 190.

Thereafter, a color filter layer (not shown) and a microlens (not shown) may be further formed, preferably a single color filter and microlens over each electrode/photodiode (PIN diode) stack, corresponding to a unit pixel.

### Second Embodiment

FIG. 2 shows a cross-sectional view of an image sensor according to a second embodiment.

An image sensor according to a second embodiment includes a substrate 110, the first electrodes 140, the intrinsic layers 170, the second conductive type conduction layers 180, second electrodes 190, and a dielectric 160. CMOS circuitry including a lower interconnection 120 is disposed on the substrate 110. The first electrodes 140 are isolated from each other, and the intrinsic layers 170 are isolated from each other. Also, the second conductive type conduction layers 180 are isolated from each other, and the second electrodes 190 are isolated from each other. The first electrode 140, the intrinsic layer 170, and the second conductive type conduction layer 180 are generally sequentially stacked on the substrate 110. The dielectric 160 is disposed between the first electrodes 140, the intrinsic layers 170, the second conductive type conduction layers 180, and the second electrodes 190. The image sensor further includes an upper interconnection 245. The upper interconnection 245 generally comprises a dark (e.g., opaque, or at least partially light-blocking) metal. For example, the upper interconnection 245 may comprise, but is not limited to, one or more of tungsten and titanium-tungsten.

According to the second embodiment, since the upper interconnection 245 comprises a dark or opaque metal, the upper interconnection 245 blocks light together with the dielectric 160 to efficiently prevent cross talk between adjacent pixels.

In the image sensor and the method for manufacturing the same according to the embodiments, the transistor circuitry and the photodiode may be vertically stacked. According to various embodiments, the transparent electrode comprising Al-doped ZnO and/or Ga-doped zinc oxide can be adopted to provide the image sensor with a non-explosive transparent electrode. Embodiments of the invention can also provide the image sensor in which the transparent electrode using Al-doped ZnO or Ga-doped zinc oxide can be adopted to reduce the manufacturing cost of the transparent electrode and the method for manufacturing the same.

Embodiments of the invention can also provide the image sensor in which the dark metal can be adopted to prevent the cross talk between the pixels and the method for manufacturing the same.

According to the embodiments, a fill factor may increase to almost 100% by vertically stacking the transistor circuit and the photodiode. In addition, the sensitivity of the image sensor can be higher than that of a related image sensor having the same pixel size by vertically stacking the transistor circuit and the photodiode.

According to the embodiments, the fabricating cost of the image sensor can be less than that of the related art image sensor having the same resolution. In addition, each unit pixel can have a more complicated circuit without reducing the sensitivity.

An additional on-chip that can be stacked according to the embodiments can improve a performance of the image sensor. In addition, the semiconductor device design rules can be easily shrunk, and the manufacturing cost can be further reduced. Also, the vertical type photodiode can be adopted to reduce, minimize or prevent the defects occurring in the photodiode.

Any reference in this specification to “one embodiment,” “an embodiment,” “exemplary embodiment,” etc., means that a particular feature, structure, or characteristic described in connection with the embodiment is included in at least one embodiment of the disclosure. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with others of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An image sensor comprising:
a substrate including circuitry with a lower interconnection;
first electrodes, intrinsic layers, and second conductive type conduction layers in sequence on the substrate; and
second electrodes on the second conductive type conduction layers, the second electrodes comprising a transparent electrode.

2. The image sensor according to claim 1, further comprising a dielectric between the first electrodes, the intrinsic layers, the second conductive type conduction layers, and the second electrodes, configured to isolate adjacent first electrodes, intrinsic layers, and second conductive type conduction layers from each other.

3. The image sensor according to claim 2, further comprising an upper interconnection electrically connecting adjacent second electrodes.

4. The image sensor according to claim 3, wherein the upper interconnection comprises a dark or opaque metal.

5. The image sensor according to claim 1, further comprising a first conductive type conduction layer between the first electrode and the intrinsic layer.

6. The image sensor according to claim 1, wherein the second electrode comprises at least one of Al-doped ZnO, Ga-doped zinc oxide, and Al- and Ga-doped ZnO.

7. The image sensor according to claim 1, wherein the second conductive type is a P-type.

8. The image sensor according to claim 5, wherein the first conductive type is an N-type.

9. The image sensor according to claim 1, wherein the intrinsic layers and second conductive type conduction layers form a plurality of photodiodes.

10. The image sensor according to claim 5, wherein the first conductive type conduction layers, the intrinsic layers and the second conductive type conduction layers form a plurality of photodiodes.

11. A method for manufacturing an image sensor, the method comprising:
forming circuitry including a lower interconnection on a substrate;
sequentially forming a first electrode, an intrinsic layer, and a second conductive type conduction layer on the substrate; and
forming a second electrode on the second conductive type conduction layer, the second electrode being a transparent electrode.

12. The method according to claim 11, further comprising:
selectively etching the first electrode, the intrinsic layer, the second conductive type conduction layer, and the second electrode to form a trench, thereby dividing the first electrode, intrinsic layer, the second conductive type conduction layer, and the second electrode; and
forming a dielectric in the trench.

13. The method according to claim 12, further comprising forming an upper interconnection electrically connecting the divided second electrodes.

14. The method according to claim 13, wherein the upper interconnection comprises a dark or opaque metal.

15. The method according to claim 11, further comprising forming a first conductive type conduction layer on the first electrode before forming the intrinsic layer.

16. The method according to claim 11, wherein the second electrode comprises at least one of Al-doped ZnO, Ga-doped zinc oxide, and Al- and Ga-doped ZnO.

17. The method according to claim 16, wherein the second electrode is formed using at least one of a sputtering system, an e-beam evaporation system, a molecular beam epitaxy system and a laser system.

18. The method according to claim 11, wherein the second electrode is formed using at least one of a sputtering system, an e-beam evaporation system, a molecular beam epitaxy system and a laser system.

19. The method according to claim 11, wherein the second electrode is formed at a temperature ranging from about 10° C. to about 400° C.
